(19) United States
(12) Patent Application Publication
(10) Pub. No.: US 2023/0007801 A1
(43) Pub. Date: Jan. 5, 2023

(54) INSTALLATION MODULES

(71) Applicant: Hewlett-Packard Development Company, L.P., Spring, TX (US)

(72) Inventors: Tien Liang CHUNG, Taipei City (TW); Chien-Yi WANG, Taipei City (TW); Justin Tinhsi Lee, Taipei City (TW)

(21) Appl. No.: 17/781,329

(22) PCT Filed: Dec. 6, 2019
(86) PCT No.: PCT/US2019/064996

§ 371 Date: May 31, 2022

(51) Int. Cl. H05K 7/14

(52) U.S. Cl. CPC H05K 7/1405; H05K 7/1407

(57) ABSTRACT

Examples of an installation module for installing a circuit-based component are described. The installation module comprises a base plate having a pair of longitudinal edges and a pair of lateral edges. The installation module may further include a supporting element to support a circuit-based component installed within the installation module. The installation module may further include first wall, a second wall and a back wall. In an example, a retaining element to retain the circuit-based component when installed, may be provided on one of the first wall and the second wall. The back wall may further include a tab which extends from a longitudinal edge of the back wall, and when pulled, is to disengage the installation module from a chassis of a computing device.

### BACKGROUND

An electronic device, such as a computing device, includes a chassis onto which various components of the electronic device may be installed. The chassis may provide physical support and electrical connectivity for such components. The components may be mounted or fitted onto the chassis using a variety of installation means, such as hooks, tabs, channels, screws, etc. Furthermore, examples of such components include, but are not limited to, motherboards, power supplies, memory cards or other components that are implemented on a circuit board (such as a printed circuit board or a PCB).

### BRIEF DESCRIPTION OF DRAWINGS

The features, aspects, and advantages of the present subject matter will be better understood with regard to the following description and accompanying figures. The use of the same reference number in different figures indicate similar or identical features and components.

FIG. 1 illustrates a perspective view of an installation module, in accordance with an example of the present subject matter;

FIG. 2 illustrates a perspective view of an assembled installation module, in accordance with an example of the present subject matter;

FIG. 3 illustrates an electronic device with an assembled installation module, in accordance with an example of the present subject matter;

FIGS. 4-5 illustrate different views of an installation module, in accordance with another example of the present subject matter; and

FIG. 6 depicts the installation of a circuit-based component within an installation module, in accordance with another example of the present subject matter; and

FIG. 7 depicts the installation of an assembled installation module onto a chassis of an electronic device, in accordance with another example of the present subject matter.

### DETAILED DESCRIPTION

In some electronic devices, components may be installable as circuit-based components. The circuit-based components include a plurality of discrete electrical or electronic components which are structurally and electrically supported by a circuit board, such as printed circuit boards. Such circuit-based components may also include interfaces that allow the circuit-based component to be electrically coupled with other components of the electronic device. An example of an electronic device includes, but is not limited to, a processor-based computing device.

The circuit-based component may further include through-holes of standard size, and at predefined position and location which may aid in mounting of the circuit-based component onto the chassis of the electronic device. For mounting, the holes provided on the circuit-based component may be aligned with corresponding apertures provided on the chassis. Thereafter screws or other coupling mechanisms may be used for mounting the installable component onto the chassis of the electronic device. Once the circuit-based component is mounted, it may be electrically coupled to a main circuitry of the electronic device through interfaces.

Such additional components may be installed onto the chassis of the electronic device as described above. As would be understood, the installation of such additional components may involve using tools and in other cases may also involve some level of skill. Furthermore, installation of such additional components may have to be performed with care to ensure that neither the additional component, the previously existing components, nor the circuitry of the electronic device gets damaged. In addition to being prone to physical damage, the circuit-based component may also be prone to damage owing to static electricity. Such challenges would also be present when the installed components are to be removed or replaced. The removal of such components may also necessitate use of tools or may involve some level of skill on the part of personnel tasked with the removal of such components.

Examples of an installation module for installing a circuit-based component are described. The circuit-based component may include a variety of electrical components, electronic components, or a combination of such different types of components. For installation, the circuit-based component may be initially fitted into the installation module. Once the circuit-based component is fitted, the assembled installation module may be mounted onto a chassis of an electronic device into which the circuit-based component were to be installed. The assembled installation module may further include a plurality of mounting elements which enable the engagement between the assembled installation module and the chassis. Since the assembled installation module (and in turn the circuit-based component) engages with the chassis through the mounting elements no other tools or external coupling mechanism (for example, screws) may be required.

In an example, the installation module includes a planar base plate (referred to as the ‘base plate’) onto which the circuit-based component, when fitted into the installation module, is placed. In an example, the base plate includes a supporting element, which is to support the circuit-based component when fitted into the installation module. The base plate of the installation module further includes a pair of longitudinal edges and lateral edges. The installation module may further include a first wall and a second wall. The first wall and the second wall may be substantially orthogonal with respect to the base plate and extend from a first lateral edge and a second lateral edge of the base plate, respectively.

The first wall and the second wall may be further provided with retaining elements. The retaining elements retain the circuit-based component when it is installed or fitted within the installation module. In addition to the first wall and the second wall, the installation module may further include a back wall. The back wall, in an example, may also be substantially orthogonal to the base plate and extends from one of the longitudinal edges of the base plate. As would be noted, the base plate along with the first wall, the second wall and the back wall provide an enclosing space within which the circuit-based component is accommodated when installed within the installation module. In another example, the installation module may be further provided with a plurality of engaging elements through which the installation module is attached to the chassis of the electronic device.

In an example, the installation module may include a tab that extends from a longitudinal edge of the back wall. The tab, when pulled, results in the separation of the engaging elements from the chassis and enables the disengagement the installation module. As a result, the installation module may be detached from the chassis without any risks of damage to the circuit-based component or the chassis of the electronic device.

It may be noted that the example installation module as described reduces the number of additional parts, such as screws, nut, and bolts, for performing the installation of the circuit-based component within an electronic device. The installation of the circuit-based components is also easier and quicker and may not involve skilled supervision or personnel. Furthermore, the tab permits users to detach the installation module from the chassis without any risks of damage to the circuit-based component or the chassis of the electronic device.

As is described in the following paragraphs, the installation module provides for an efficient mechanism for mounting or fixing of the circuit-based components with minimal efforts. Furthermore, the installation modules as described are also less complex, and hence, would be cost effective and economical. In an example, the assembling of the circuit-based components onto the installation module is further described in conjunction with the accompanying figures. Wherever possible, the same reference numbers are used in the drawings and the following description to refer to the same or similar parts.

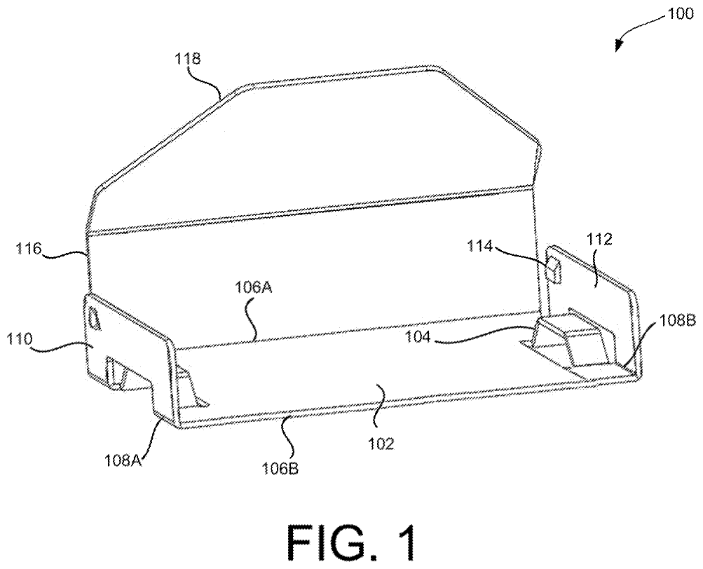

FIG. 1 illustrates a perspective view of an installation module 100, as per an example of the present subject matter. A circuit-based component may be installed within an electronic device (not shown in FIG. 1) by installing the circuit- based component within the installation module 100, and then subsequently mounting the resulting assembled installation module 100 onto the chassis of an electronic device. It may be noted that the installation module 100 as illustrated depicts only one example. Other examples may also be possible without deviating from the scope of the subject matter of the claims.

Returning to FIG. 1, the installation module 100 includes a planar base plate 102. The planar base plate 102 (referred to as the base plate 102) further includes supporting element 104 which is to support the circuit-based component (not shown in FIG. 1) when installed within the installation module 100. Continuing with the present example, the base plate 102 has a pair of longitudinal edges 106A, 106B (collectively referred to as longitudinal edges 106) and lateral edges 108A, 108B (collectively referred to as the lateral edges 108). The longitudinal edges 106 and lateral edges 108 are such that they form the opposite edges of the base plate 102.

The installation module 100 may further include a first wall 110 and a second wall 112. The first wall 110 and the second wall 112 extend from the lateral edges 108A, 108B, respectively. The orientation of the first wall 110 and the second wall 112 is such that the first wall 110 and the second wall 112 are substantially orthogonal with respect to the base plate 102. Both the first wall 110 and the second wall 112 extend in a manner such that they form an interior portion within which the circuit-based component may be installed. It may be understood, that the term substantially orthogonal may refer to instances wherein the first wall 110 and the second wall 112 at an angle of about 90 degrees with respect to the base plate 102, within acceptable tolerance limits. In an example, the first wall 110 and the second wall 112 may be further provided with a retaining element 114. The retaining element 114, when the circuit-based component is installed, is to retain the circuit-based component within the installation module 100.

The installation module 100 may further include a back wall 116. The back wall 116, in an example, is also substantially orthogonal to the base plate 102 and extends from a longitudinal edge, e.g., longitudinal edge 106A of the base plate 102. The back wall 116 is such that it emanates from the longitudinal edge 106 A. Continuing with the present example, the installation module 100 may be further provided with a tab 118. The tab 118 extends from a longitudinal edge of the back wall 116. In an example, the tab 118 extends away from the back wall 116.

As mentioned previously, the circuit-based component may be installed by initially installing the circuit-based component into the installation module 100, which may then be mounted onto a chassis of an electronic device. In an example, the tab 118 is to permit manually disengaging the installation module 100 from the chassis onto which it may be fitted. To disengage, the tab 118 may be manually pulled in a direction that extends away from the back wall 116. Owing to the tab 118, the installation module 100 may be disengaged manually with minimal efforts. Furthermore, removing the installation module 100 from the chassis may be performed without any tools with the tab 118 providing a mechanism for enabling removal of the installation module 100 from even restricted spaces. It may be noted that the above-mentioned examples are only indicative. Other examples of the installation module 100 are also possible which would also fall within the scope of the present subject matter. Such other examples are described in further detail in conjunction with the other figures.

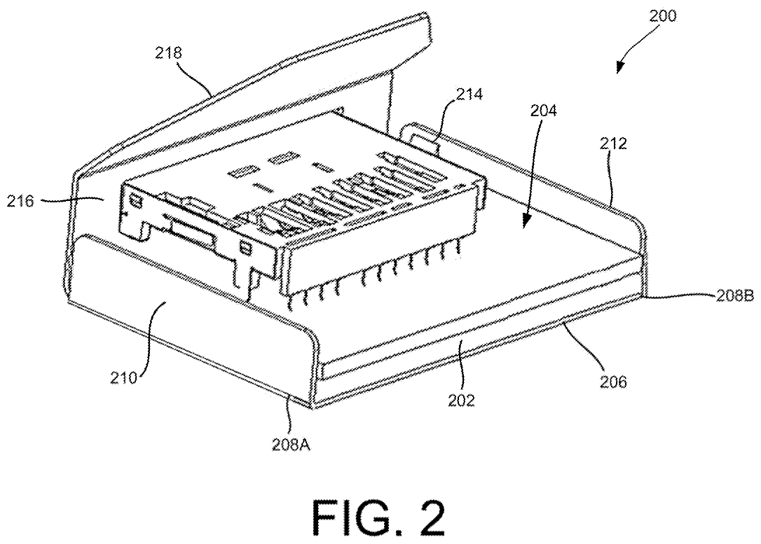

FIG. 2 illustrates a perspective view of an assembled installation module 200, as per an example of the present subject matter. The assembled installation module 200 includes a planar base plate 202. The planar base plate 202 (referred to as the base plate 202) is to support a circuit-based component 204 installed within the assembled component module 200. The circuit-based component 204 may include electronic circuitry that may be implemented on a circuit board. The electronic circuitry, in an example, may either include a plurality of electrical or electronic components, or may include an integrated circuit-based component. In an example, the circuit-based component 204 may include components such as an input/output hub (I/O hub), connectors, and ports. It may be noted that the examples of such components is only indicative and should be not be construed as a limitation.

The base plate 202 may include a longitudinal edge 206 and a pair lateral edges 208A, 208B. The lateral edges 208A, 208B (collectively referred to as the lateral edges 208) are such that they form opposite edges of the base plate 202. Similar to the installation module 100, the assembled installation module 200 may further include a first wall 210 and a second wall 212. The first wall 210 and the second wall 212 extend from a lateral edge 208A, 208B, respectively. The orientation of the first wall 210 and the second wall 212 is such that the first wall 210 and the second wall 212 are substantially orthogonal with respect to the base plate 202 so as to define an interior portion of the installation module 200 within which the circuit-based component 204 is to be received and installed. In an example, the first wall 210 and the second wall 212 may be further provided with retaining element 214. As will be explained subsequently, the retaining element 214 is to retain the circuit-based component 204 installed within the installation module 200.

The assembled installation module 200 also includes a back wall 216. The back wall 216 is substantially orthogonal to the base plate 202, similar to the first wall 210 and the second wall 212, and extends from another longitudinal edge of the base plate 202. In an example, the other longitudinal edge of the installation module 200 may be an edge which lies opposite to the longitudinal edge 206. The assembled installation module 200 may be further provided with a tab 218, which in turn extends from a longitudinally extending edge of the back wall 216. In an example, the tab 218 extends away from the back wall 216 and may be inclined with respect to the base plate 202. Within the assembled component module 200, the circuit-based component 204 is installed. The circuit- based component 204, when installed within the assembled component module 200, is retained by the retaining element 214. In an example, the retaining element 214 may provide a mechanism which allows the circuit-based component 204 to be snapped into and retained within the assembled component module 200. Once the assembled installation module 200 is mounted onto a chassis of an electronic device, the tab 218 may be manually pulled to disengage the assembled installation module 200 from the chassis with minimal efforts and without any tools. In an example, the removal may be performed even in restricted spaces.

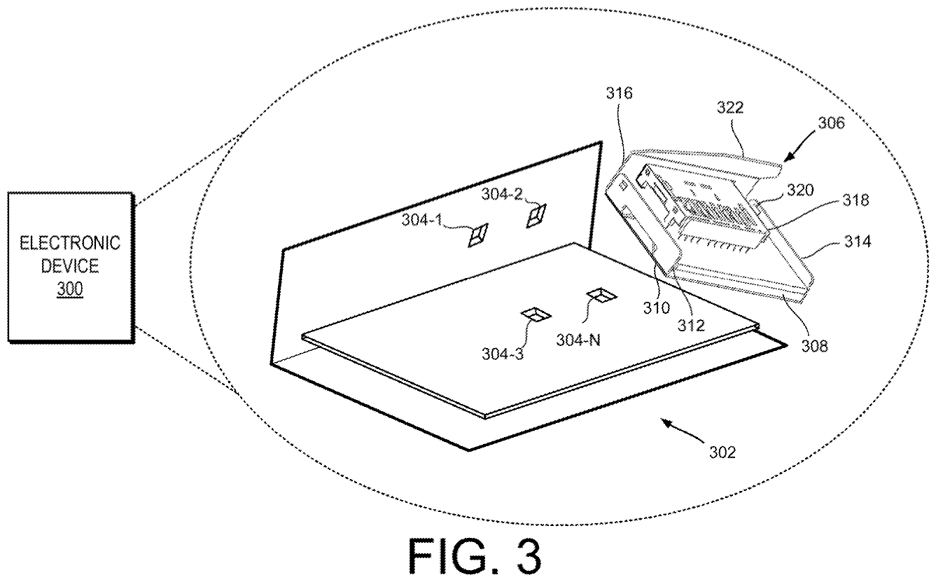

FIG. 3 illustrates a magnified view of a portion of an electronic device 300, as per an example of the present subject matter. The electronic device 300 may be any device which operates based on electrical signals for performing certain functions. Examples of electronic device 300 include, but is not limited to, a computing device such as a desktop personal computer (PC), notebook PC, workstation or mobile workstation, imaging device, or another type of computing device. It may be understood that electronic device 300 may be any other type of electronic device without deviating from the scope of the present subject matter. Returning to the present example, FIG. 3 provides a magnified view of a portion of the electronic device 300. As illustrated, the electronic device 300 may include a chassis 302. The chassis 302 may be considered as a portion of a housing of the electronic device 300. In an example, the chassis 302 may be a structural frame onto which the components may be mounted. The chassis 302 may further include a plurality of chassis slots 304-1, 304-2, . . . , 304-N (collectively referred to as chassis slots 304). In the present example, the chassis 302 may be further fitted with a component installation module 306, similar to the assembled installation module 200. For fitting onto the chassis 302, the component installation module 306 is to engage with chassis slots 304. These aspects are further described subsequently. In an example, the component installation module 306 is removably fitted onto the chassis 302 of the electronic device 300. The component installation module 306 in turn further includes a base plate 308. The base plate 308 has a first lateral edge 310 from which a first wall 312 extends. In a similar manner, the component installation module 306 further includes a second wall 314 which in turn extends from a second lateral edge (not visible in FIG. 3). In an example, the first wall 312 and the second wall 314 are substantially orthogonal to the base plate 308.

The component installation module 306 may be further provided with a back wall 316 which extends from a first longitudinal edge (not visible in FIG. 3) of the base plate 308. In an example, the back wall 316 is such that it is substantially orthogonal with respect to the base plate 308. In an example, first wall 312, the second wall 314 and the back wall 316 form an enclosed space within which a circuit-based component 318 may be installed. In an example, a retaining element 320 may be provided on one of the first wall 312 and the second wall 314. For example, even though FIG. 3 depicts the retaining element 320 to be present on the second wall 314, the retaining element 320 may be present either alternatively or additionally, on the first wall 312.

Proceeding further, the component installation module 306 may include a tab 322. The tab 322 extends from and away from a longitudinal edge of the back wall 316. In an example, the tab 322 enables manually disengaging the component installation module 306 from the chassis 302 by pulling the tab 322. The disengaging may be affected with minimal efforts, without any tools, and may even be performed in restricted spaces.

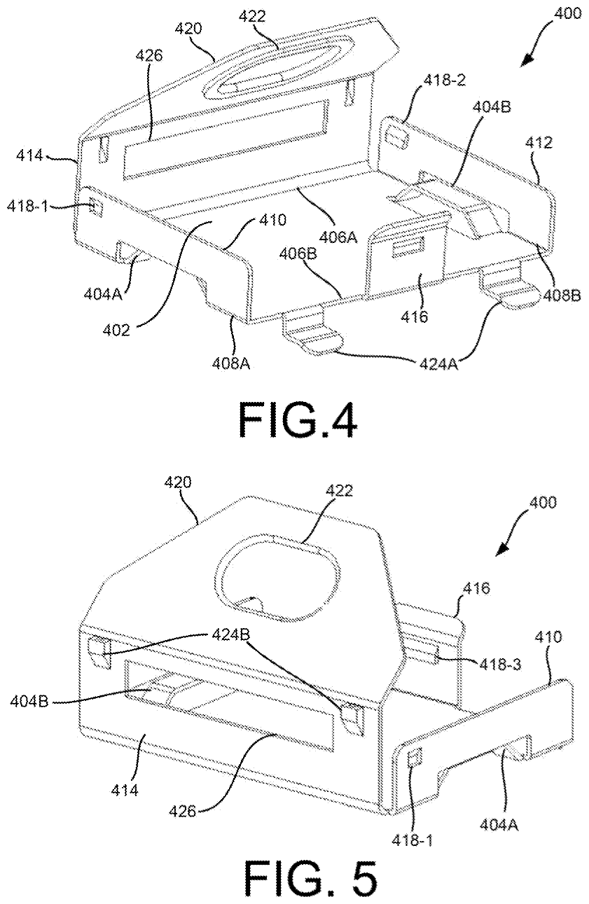

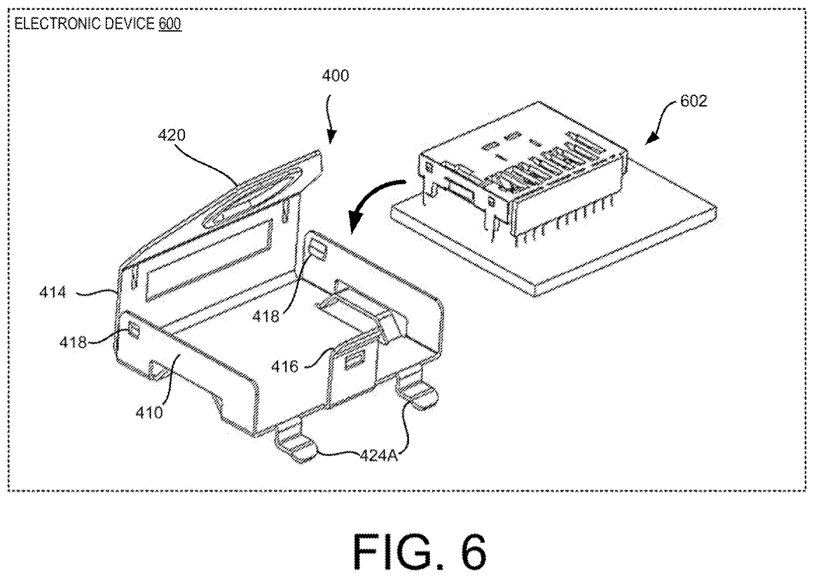

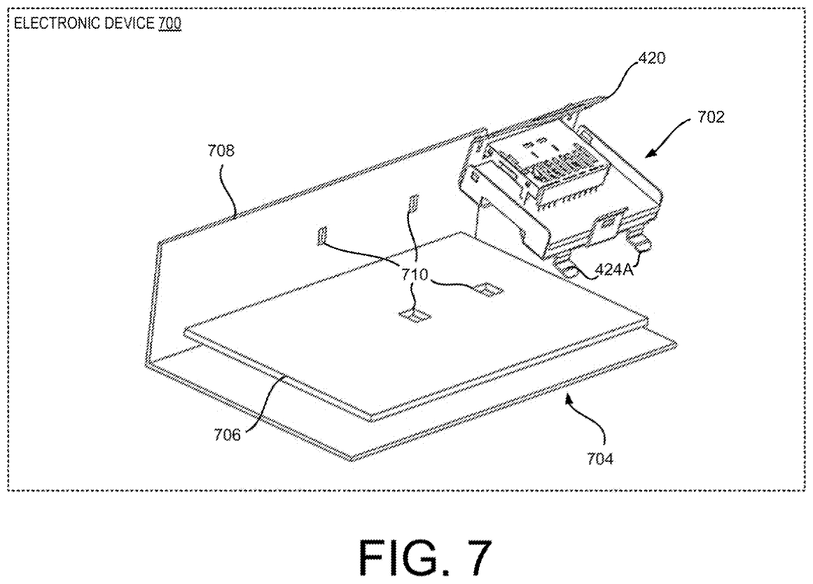

FIGS. 4-5 depicts different views of an installation module 400, as per an example. The installation module 400 includes a planar base plate 402 onto which a circuit-based component (as will be explained in conjunction with FIGS. 6-7) is placed when such a circuit-based component is installed within the installation module 400. In an example, the base plate 402 includes supporting elements 404A, 404B. The supporting elements 404A, 404B (collectively referred to as supporting elements 404) are to support the circuit-based component when it is installed within the installation module 400. It may be noted that even though FIGS. 4-5 depict a pair of supporting elements 404, the installation module 400 may include an additional number of supporting elements 404 without deviating from the scope of the present subject matter.

Returning to the present example, the base plate 402 of the installation module 400 further includes a pair of longitudinal edges 406A, 406B (collectively referred to as longitudinal edges 406) and lateral edges 408A, 408B (collectively referred to as lateral edges 408). The installation module 400 further includes a first wall 410 and a second wall 412. The first wall 410 and the second wall 412 are such that they extend from the lateral edges 408A, 408B. In an example, the first wall 410 and the second wall 412 are substantially orthogonal to the base plate 402, as they extend from the respective the lateral edges 408A, 408B.

The installation module 400 may further include a back wall 414 which extends from one of the longitudinal edges 406, e.g., longitudinal edge 406A. The back wall 414, similar to the first wall 410 and the second wall 412, is also substantially orthogonal to the base plate 402. In an example, the installation module 400 may further be provided with a retaining tab 416. In the example as illustrated, the retaining tab 416 is provided on the longitudinal edge 406B. The retaining tab 416 is also such that it is substantially orthogonally with respect to the base plate 402. In an example, the retaining tab 416 is of a resilient material such that the retaining tab 416 is biased in a direction towards the back wall 414.

As depicted in the present example, the first wall 410, the second wall 412 and the back wall 414 form a perimeter which extends along the lateral edges 408 and one of the longitudinal edges 406, i.e., the longitudinal edge 406A. It may be noted that the first wall 410, the second wall 412, and the back wall 414, along with the retaining tab 416 provide an enclosing space within which a circuit-based component may be installed. In an example, the retaining tab 416 is located on a longitudinal edge 406B which is opposite to the back wall 414, with the retaining tab 416 is substantially orthogonal with respect to the base plate 402.

In an example, the first wall 410 and the second wall 412 may be provided with a plurality of retaining elements 418-1 and 418-2, with an additional retaining element 418-3 being provided on an inner surface of the retaining tab 416. The retaining elements 418-1, 418-2 and 418-3 (collectively referred to as the retaining elements 418) are to retain a circuit-based component when it is installed within the installation module 400. In an example, the retaining elements 418 may be in the form of protrusions which may be provided on the respective inner surfaces of the first wall 410, the second wall 412, back wall 414, and the retaining tab 416.

The installation module 400 may further include a disengaging tab 420 which extends from a longitudinal edge of the back wall 420. In an example, the disengaging tab 420 is such that it extends over the base plate 402 of the installation module 400. In an example, the disengaging tab 420 may be inclined to the base plate 402.

The disengaging tab 420 may further include an opening 422 provided through the disengaging tab 420. In an example, the opening 422 permits the disengaging tab 420 to be manually held and pulled in order to disengage the installation module 400 from a chassis of an electronic device. In an example, the installation module 400 is to be fitted onto chassis of an electronic device. To this end, the installation module 400 may further include a pair of front engaging members 424A and a pair of rear engaging members 424B. In the present example, the front engaging members 424A may be provided on longitudinal edge 406B of the base plate 402. In another example, the installation module 400 may further include rear engaging members 424B provided on an outer surface of the back wall 414. The front engaging members 424A and a pair of rear engaging members 424B (collectively referred to as engaging members 424) enable the engagement of the installation module 400 to a chassis of the electronic device, when the installation module 400 is fitted thereto.

In yet another example, the back wall 414 may further include a longitudinally extending vent 426 or an opening 426. In an example, the opening 426 or vent 426 extends across a length of the back wall 414. The vent 426, in an example, enables ventilation for dissipation of heat and may also enable reduction in weight of the installation module 400 at the time of manufacturing the installation module 400.

As described, the retaining elements 418 retain and hold a circuit- based component in position when the same is installed within the installation module 400. Additionally, the engaging members 424 permit the installation module 400 (when fitted with the circuit-based component) to be fitted onto a chassis of an electronic device. The manner in which the installation of the circuit- based component may be performed, is further explained in conjunction with FIGS. 6-7.

FIG. 6 depicts the installation, within an example electronic device 600, of a circuit-based component 602 within the installation module 400 (as was described in conjunction with FIG. 4). For installation, the circuit-based component 602 may be manually positioned within the space defined by the first wall 410, the second wall 412, and the back wall 414. As the circuit-based component 602 is being laid within the installation module 400, the edges of the circuit-based component 602 may encounter the retaining elements 418 (although not depicted in FIG. 6) which are provided on the inner surface of first wall 410, the second wall 412, the back wall 414 and the retaining tab 416. In an example, the obstruction caused by the retaining elements 418 may be overcome by applying an insertion force. Under the effect of the insertion force, the edges of the circuit-based component 602 may abut against and urge the retaining elements 418 in an outward direction. As the retaining elements 418 move outward, an appropriate passage is provided to the circuit-based component 602 which may move further inwards towards the base plate 402 into the installation module 400. As the edges of the circuit-based component 602 cross the retaining elements 418, the retaining elements 418 assume their original position, thereby removably securing the circuit-based component 602 within the installation module 400. In an example, the circuit-based component 602, when inserted into the installation module 400, is supported by the supporting elements 404. The resulting assembled installation module 400 (as depicted in FIG. 7) may then be fitted onto the chassis of an electronic device as is described in conjunction with FIG. 7.

FIG. 7 depicts installation, within an example electronic device 700, of assembled installation module 702 onto a chassis 704 of an electronic device. It may be noted the present description is provided in conjunction with the installation module 400 described in the preceding figures. The chassis 704 of the electronic device 300 is depicted as including a base surface 706 and a chassis wall 708. The base surface 706 and the chassis wall 708 may further include a plurality of chassis slots 710. In an example, the engaging members 424 provided onto the installation module 400 engages with the corresponding chassis slots 710 provided on the chassis 704.

For fitting the assembled installation module 702 onto the chassis 704 of the electronic device 700, an installation positioned may be initially identified. Once the installation position is identified, the assembled installation module 702 may be manually positioned. In an example, a user may align the engaging members 424 of the assembled installation module 702 with the corresponding chassis slots 710 provided on the chassis 704. Once the assembled installation module 702 is suitably positioned, the assembled installation module 702 may be eased towards the base surface 706 such that the engaging members 424 engage and lock into the chassis slots 710 provided on the base surface 706 of the chassis 704. In a similar manner, the assembled installation module 702 may be urged towards the chassis wall 708 so as to enable engagement between them.

In an example, the disengaging tab 420 is to permit manually disengaging the installation module 400 from the chassis 704. To this end, the disengaging tab 420 may be manually pulled in a direction away from the back wall 414. In response to the pulling of the disengaging tab 420, the engaging members 424 disengage from the corresponding chassis slots 710 thereby enabling the separation of the assembled installation module 702 from the chassis 704 of the electronic device 700. In an example, the back wall 414 may be of a resilient member which allows the engaging members 424 to be pulled away from the chassis slots 710 to remove the installation module 400 from the chassis 704. The removal of the installation module 400 from the chassis 704 may be performed manually with minimal efforts, without any tools and may be used for removing or replacing the circuit-based component 602 from a restricted space of the electronic device 700.

Although implementations of present subject matter have been described in language specific to structural features and/or methods, it is to be noted that the present subject matter is not necessarily limited to the specific features or methods described. Rather, the specific features and methods are disclosed and explained in the context of a few implementations for the present subject matter.

I/we claim:

1. An installation module comprising:
a base plate, wherein the base plate comprises a pair of longitudinal edges and a pair of lateral edges;
a supporting element provided on the base plate, wherein the supporting element is to support a circuit-based component when the circuit-based component is installed within the installation module;
a first wall extending from a first lateral edge of the base plate;
a second wall extending from a second lateral edge, wherein the first lateral edge and the second lateral edge are one of the pairs of lateral edges of the base plate and are substantially orthogonal to the base plate;
a retaining element provided on one of the first wall and the second wall, wherein the retaining element is to retain the circuit-based component when installed;
a back wall extending substantially orthogonally from a longitudinal edge of the base plate; and
a tab extending from a longitudinal edge of the back wall, wherein the tab, when pulled, is to disengage the installation module from a chassis of an electronic device.

2. The installation module as claimed in claim 1, further comprising a retaining tab provided on another longitudinal edge of the base plate, wherein the another longitudinal edge is an edge which lies opposite to the longitudinal edge of the base plate.

3. The installation module as claimed in claim 1, wherein the back wall and the base plate comprises engaging elements, wherein the engaging elements are to engage with slots provided on the chassis.

4. The installation module as claimed in claim 1, wherein the tab comprises an opening, wherein the opening is to permit the disengaging tab to be manually held and pulled to disengage the installation module from the chassis of the computing device.

5. The installation module as claimed in claim 1, wherein the back wall comprises an opening extending across a length of the back wall.

6. An assembled installation module, comprising:
a planar base plate;
a first wall and a second wall extending from a first lateral edge and a second lateral edge of the base plate, wherein the first wall and the second wall are substantially orthogonal to the base plate;
a retaining element provided on one of the first wall and the second wall;
a circuit-based component fitted onto the base plate, wherein the circuit- based component when installed onto the base plate is retained by the retaining element;
a back wall extending from a longitudinal edge of the base plate, wherein the back wall is substantially orthogonal to the base plate; and
a tab extending from a longitudinal edge of the back wall, wherein the tab, when manually pulled, is to disengage the assembled installation module from a chassis of a computing device.

7. The assembled installation module as claimed in claim 6, wherein the base plate comprises a supporting element, wherein the supporting element is to support the circuit-based component when the circuit-based component is installed within the assembled installation module.

8. The assembled installation module as claimed in claim 6, wherein the base plate comprises a retaining tab located on an edge opposite to the back wall and is to extend from the base plate.

9. The assembled installation module as claimed in claim 6, wherein the circuit-based component is one of an Input/Output hub (I/O hub), a connector, and a port

10. The assembled installation module as claimed in claim 6, wherein the retaining element is in form of a protrusion provided on inner surfaces of one of the first wall and the second wall.

11. An electronic device comprising:
a chassis, having a plurality of chassis slots; and
a component installation module removably fitted onto the chassis of the electronic device, the component installation module further comprising:
a base plate;
a first wall and a second wall extending substantially orthogonally from a first lateral edge and a second lateral edge of the base plate, wherein the first wall and the second wall comprises a plurality of engaging elements to engage with corresponding chassis slots from amongst the plurality of chassis slots;
a back wall extending substantially orthogonally from a first longitudinal edge of the base plate;
a circuit-based component fitted onto the base plate, wherein the circuit-based component is retained by a retaining element within the component installation module; and
a tab extending from a longitudinal edge of the back wall, wherein the tab, when pulled, is to disengage the component installation module from the chassis.

12. The electronic device as claimed in claim 11, wherein the back wall and the base plate comprises engaging elements, wherein the engaging elements are to engage with the corresponding chassis slots from amongst the plurality of chassis slots.

13. The electronic device as claimed in claim 11, wherein the base plate comprises a supporting element, wherein the supporting element is to support the circuit-based component installed within the component installation module.

14. The electronic device as claimed in claim 11, wherein the back wall comprises a longitudinally extending vent.

15. The electronic device as claimed in claim 11, wherein the tab comprises an opening, wherein the opening is to permit the tab to be manually held and pulled to disengage the component installation module installed with the circuit- based component from the chassis of the electronic device.
